(19) United States
(12) Patent Application Publication
(10) Pub. No.: US 2006/0022710 A1
(43) Pub. Date: Feb. 2, 2006

(54) Integrated circuit having an input/output terminal configurable within a given voltage range

(75) Inventors: Herve Chalopin, Aubagne (FR); Laurent Tabaries, Aubagne (FR)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics SA, Montrouge (FR)

(21) Appl. No.: 11/170,760

(22) Filed: Jun. 28, 2005

(30) Foreign Application Priority Data
Jun. 30, 2004 (FR) 04 07245

(51) Int. Cl. H03K 19/0175

(52) U.S. Cl. 326/82

(57) ABSTRACT

A circuit disposes of a power supply terminal dedicated to the power supply V_{IO} of the input/output terminals in order that these terminals may be used by a customer in a voltage range of their choice. The input/output terminals produced according to the invention include transposition means that allow the voltage of the signal flowing through them to be adapted from a first voltage range to a second voltage range.

### BACKGROUND OF THE INVENTION

1. Field of the Invention

The invention relates to an integrated circuit having an input/output terminal configurable within a voltage range. The invention is applicable to all types of integrated circuit.

2. Description of the Related Art

Integrated circuits are circuits generally fabricated on silicon and include a circuit core communicating with the outside by means of a plurality of terminals.

The terminals of an integrated circuit can be of several categories. There are power supply terminals, such as a ground terminal and one or more terminals for a supply voltage VDD, or possibly V_{DD1}, V_{DD2}, etc., that deliver the voltages powering the integrated circuit. There are also input/output terminals allowing data to be exchanged between the integrated circuit and its external environment, in one direction and/or in the other. The input/output terminals include a conducting pad that is used to interconnect the integrated circuit with the outside, either by means of a bonding wire connected to a connecting pin of a housing, or directly by soldering onto a printed circuit board receiving the integrated circuit, or else for being connected by another method. The terminals also include protection means generally used to avoid voltage surges (electrostatic protection of the ESD type or other). In the case of an input and/or output terminal, the terminal includes, in addition, adaptive means designed to adapt the internal signals of the circuit to the external signals of the circuit.

Currently, a known solution is to have circuits operating according to one or more supply voltages, and whose input/output terminals communicate with other circuits that can also operate according to one or more voltage ranges.

FIG. 1 shows an example of an integrated circuit according to the state of the art. This integrated circuit includes a first circuit core 10 and a second circuit core 20. Each circuit core 10 and 20 operates with its own separate supply voltage.

The supply voltages are delivered to the integrated circuit via a first power supply terminal 30, via a second power supply terminal 31 via a ground terminal 32. The ground terminal 32 is connected to ground circuit 40. The first power supply terminal 30 and the ground terminal 32 are used, for example, to supply the first circuit core 10. The second power supply terminal 31 and the ground terminal 32 are used, for example, to supply the second circuit core 20.

In addition to these power supply terminals, the circuit also includes input/output terminals, here divided into two categories. The first category corresponds to first input/output terminals 33 connected to a power supply network 41 coupled to the first power supply terminal 30. Second input/output terminals 34 are connected to a second power supply network 42 that is coupled to the second power supply terminal 31. When an input/output terminal is supplied by a power supply voltage, this input/output terminal can receive signals, coming from the outside, that are in a voltage range between zero volts and the supply voltage at which this terminal is supplied. Thus, the first input/output terminals 33 can exchange signals with the outside at a voltage level in the range between zero volts and the supply voltage of the first power supply terminal 30. The second input/output terminals 34 can exchange signals with the outside whose voltage range extends from zero volts up to the supply voltage of the second power supply terminal 31. In the design of the integrated circuit, the choices regarding the supply of the first and second input/output terminals 33 and 34 are made depending on the constraints imposed by the circuits to be connected to them.

However, the evolution of the art can lead to circuits generally operating in a first range of voltages being, for reasons of cost, speed, operation and size, transferred into another technology that uses a different voltage range.

When a circuit is dedicated for operation, for example, with memories operating in the range from 0 to 3.3 V, it can never control memory circuits operating in a range from 0 to 1.8 V.

However, the evolution of the art shows that memories currently operating under a voltage regime of 3.3 V could disappear in the future and be completely replaced by memories operating at 1.8 V. What is true for memories is also true for many other circuits, which do not necessarily depend on a same manufacturer. In the case of an evolution of the art, it is necessary to produce a new integrated circuit modified accordingly.

Now, a change in the power supply voltage that supplies an input/output terminal requires that the power supply circuit be redesigned. Indeed, if an input/output must change its operating range, this is not necessarily the case for all the elements connected to the same power supply circuit. However, redesigning the power supply circuit amounts to designing a new integrated circuit, and the fabrication of a new integrated circuit is a source of relatively high costs.

### BRIEF SUMMARY OF THE INVENTION

The invention solves the aforementioned problem of redesign. In order to avoid having to redesign the whole of the circuit, it is proposed that a power supply terminal be dedicated to the supply of certain of the input/output terminals in order that these terminals may be used by a customer in a voltage range of their choice. The input/output terminals produced according to the invention include voltage transposition means that allow the voltage of the signal flowing through them to be adapted from a first voltage range to a second voltage range.

More particularly, the subject of the invention is an integrated circuit having a circuit core powered by at least one power supply voltage received via a first power supply terminal, and including at least one input and/or output terminal serving as a link between the circuit core and the exterior of the integrated circuit. A second power supply terminal receives a terminal supply voltage within a given voltage range, the terminal supply voltage determining an operating voltage range of the input and/or output terminal with respect to the exterior of the integrated circuit. The input and/or output terminal includes at least one adaptor circuit supplied, on the one hand, with the terminal supply voltage and, on the other hand, with the power supply voltage. The adaptor circuit performs the transposition, of a signal flowing through the input and/or output terminal, from a first voltage range between zero volts and the power supply voltage to a second voltage range between zero volts and the terminal supply voltage, or vice versa.

The second power supply terminal, preferentially, only supplies the input and/or output terminals.

### BRIEF DESCRIPTION OF THE SEVERAL VIEWS OF THE DRAWINGS

The invention will be better understood and other features and advantages will become apparent upon reading the description that follows, this description making reference to the appended figures in which:

FIG. 1 shows an integrated circuit according to the state of the art,

FIG. 2 shows an integrated circuit according to the invention,

FIGS. 3 to 5 show logic input/output terminals according to the invention.

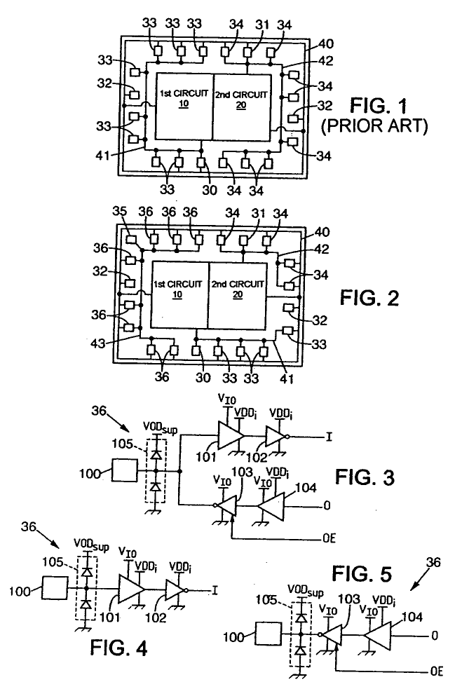

### DETAILED DESCRIPTION OF THE INVENTION

For the sake of consistency, the same reference will be used to denote the same element in all the figures and in the description. Furthermore, in order to avoid needlessly cluttering the drawings, certain elements have been purposely omitted. Some of these elements not shown are mentioned in the description or completely omitted if they are only of a very secondary nature with respect to the invention.

The integrated circuit shown in FIG. 2 includes a first circuit core 10 powered according to a first power supply voltage V_{DD1} and a second circuit core 20 powered according to a second power supply voltage V_{DD2}. The first circuit core 10 is connected to a first power supply terminal 30 by means of a first power supply circuit 41. The first circuit core 10 is also connected to a ground circuit 40, itself connected to the ground terminals 32. The second circuit core 20 is connected to a second power supply circuit 42, itself connected to a second power supply terminal 31. The second circuit core 20 is also connected to the ground circuit 40. In order to exchange data with the exterior of the integrated circuit, the first and second circuit cores 10 and 20 are connected to a plurality of input/output terminals 33, 34 and 36. These links between the circuit cores 10 and 20 and the input/output terminals 33, 34 and 36 are not shown in order to simplify the drawing. The first input/output terminals 33 are connected to the first power supply circuit 41 in order to operate in a first voltage range 0V-V_{DD1} corresponding to the first power supply voltage V_{DD1} delivered by the first power supply terminal and the first circuit 10. The second input/output terminals 34 are connected to the second power supply circuit 42, in order to operate in a second voltage range 0V-V_{DD2}, corresponding to the second power supply voltage V_{DD2} delivered by the second power supply terminal 31. Third input/output terminals 36 are connected to a third power supply circuit 43 corresponding to a power supply dedicated to the configuration of an operating voltage range of the third input/output terminals 36. A third power supply terminal 35 is connected to this third power supply circuit 43 in order to allow a customer user of the circuit to fix a third power supply voltage V_{IO} defining a voltage range 0V-V_{IO}.

Thus, the first input/output terminals 33 operate according to a first power supply voltage V_{DD1}, the second input/output terminals 34 operate according to the second power supply voltage V_{DD2}, and the third input/output terminals 36 operate according to a third voltage referred to as terminal supply voltage V_{IO} that is fixed by means of the power supply terminal 35, and independently of the other voltages used within the integrated circuit. Although independent, the terminal supply voltage V_{IO} must be in a voltage range that is compatible with the rest of the circuit. Preferentially, this terminal supply voltage V_{IO} is in the range between the minimum power supply voltage, for example V_{DD1}, and the maximum power supply voltage, for example V_{DD2}, when the integrated circuit has at least two power supply voltages.

The input/output terminals 33, 34 and 36, and especially the third input/output terminals 36, may be terminals of the input type, of the output type, or else of the input/output type, but also of the “digital” or of the “analogue” type.

FIG. 3 shows a digital input/output terminal 36 configured according to the invention. This input/output terminal 36 includes a metal pad 100 connected to an input of an input adaptor circuit 101. An output of the input adaptor circuit 101 is connected to an input of an input signal conditioning circuit 102. An output of the input signal conditioning circuit 102 delivers the input signal I to one of the circuit cores 10 or 20. The pad 100 is also connected to an output of an output signal conditioning circuit 103, an input of the signal conditioning circuit 103 is connected to an output of an output adaptor circuit 104. An input of the output adaptor circuit 104 receives an output signal 0 corresponding to a signal delivered by one of the circuit cores 10 or 20. In addition, the pad 100 is also connected to protection means 105. The input adaptor circuit 101 and the output adaptor circuit 104 can be the same kind of circuit. Indeed, these two circuits can be formed either by using a threshold circuit or by using amplifiers operating according to two power supply voltages. The ratio of the thresholds or the amplification coefficient, depending on the type of circuit used, is defined by the ratio of its two power supply voltages V_{IO} and V_{DDi}, V_{DDi} corresponding to the power supply voltage V_{DD1} or V_{DD2} of the circuit core 10 or 20, to which the terminal 36 is connected. Such adaptor circuits are known, notably for the transfer of data or other signals between two circuit cores operating at different voltages.

The input signal conditioning circuit 102 is, for example, an inverter or any other type of logic circuit in the case of a logic input. This input signal conditioning circuit is powered by the power supply voltage V_{DDi} of the circuit core 10 or 20 to which it is connected.

The output signal conditioning circuit 103 is powered by the third power supply voltage V_{IO}. This output signal conditioning circuit 103 is, for example, a NAND gate (performing the operation AND-NOT) with output validation. In the case of an input/output gate, it is advantageous to include an output validation circuit, in this case a function that is also provided by the output signal conditioning circuit 103. The purpose of the output validation circuit is to avoid configuring an output signal onto a bus to which the pad 100 might be connected while another bus element is imposing another state.

A control signal OE is delivered by the circuit core to which the terminal is connected. Depending on the type of output signal conditioning circuit, it may be necessary to add an adaptor circuit in the link of the control signal OE. The protection means 105 here are represented by two diodes limiting negative and positive voltage surges. It will be noted that the voltage denoted V_{DDsup} corresponds to the higher of the power supply voltages V_{DD1} and V_{DD2} delivered by the first and second power supply terminals 30 and 31.

The choice of using an amplifier or a threshold circuit as adaptor circuit 101 or 102 may depend on the type of signal that is transmitted through the terminal. If the transmitted signal is of the analogue type, it follows that the adaptor circuit is preferentially an amplifier. In the case where the signals are of the digital type, namely level 0 and level 1, threshold circuits that are simpler than amplifiers may suffice.

In addition, the digital input/output example shown here includes NAND gates. These NAND gates may be replaced by any other type of known gate, including known types of gates having an output validation for the output signal conditioning circuit 103.

In the case of an analogue input/output terminal, the function of the input signal conditioning circuit 102 and the output signal conditioning circuit 103 can also be provided by the adaptor circuits 101 and 104. Indeed, in the case of analogue circuits, the signal conditioning circuits are generally amplifiers already present for the voltage adaptation carried out in the input adaptor circuit 101 and the output adaptor circuit 104.

The terminals 36 can be relatively simple terminals. Indeed, these terminals may be input-only terminals such as is shown in FIG. 4. The input terminal differs from the input/output terminal by the elimination of the output path, namely of the output adaptor circuit 104 and of the output signal conditioning circuit 103.

It can also be desirable to have only an output terminal, as shown in FIG. 5. In that case, the input/output terminal in FIG. 3 is modified by the elimination of the path corresponding to the input path. The input adaptor circuit 101 and the input signal conditioning circuit 102 are therefore eliminated. It should be noted that, in the case of an output-only terminal, the output validation is not necessarily required. This remains in the circuit diagram, but could just as easily be eliminated in the case where this output is not designed to be set in a high impedance state in order to connect onto a bus.

In the example described, the terminal supply voltage V_{IO} is only used for powering the input/output terminals. However, it is possible that this power supply voltage could also power a circuit that is internal to the integrated circuit if, by way of its structure or its function, this internal circuit must operate with the same voltage as the external voltage of the terminals.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. An integrated circuit comprising:
a first power supply terminal;
a circuit core configured to receive at least one power supply voltage via the first power supply terminal;
at least one input and/or output terminal configured to serve as a link between the circuit core and an exterior of the said integrated circuit;
a second power supply terminal configured to receive a terminal supply voltage within a given voltage range, the terminal supply voltage determining an operating voltage range of the at least one input and/or output terminal with respect to the exterior of the integrated circuit; and
wherein the at least one input and/or output terminal includes at least one adaptor circuit powered by the terminal supply voltage and by the power supply voltage, the adaptor circuit being configured to transpose a signal flowing through the at least one input and/or output terminal, from a first voltage range between zero volts and the power supply voltage to a second voltage range between zero volts and the terminal supply voltage, or vice versa.

2. The integrated circuit according to claim 1 where the input and/or output terminal is an input terminal that comprises:
a pad configured to be connected to the exterior of the integrated circuit; and
a voltage adaptor circuit including an input coupled to the pad, the adaptor circuit coupled to and configured to be powered, by the terminal supply voltage and by the power supply voltage configured to transform an input signal received in a voltage range between zero volts and the terminal supply voltage into a signal in the range between zero volts and the power supply voltage.

3. The integrated circuit according to claim 2 where the input terminal is a logic input terminal that comprises a logic signal conditioning circuit having an input connected to an output of the adaptor circuit, and an output connected to the circuit core, the logic signal conditioning circuit configured to be supplied with the power supply voltage.

4. The integrated circuit according to claim 1 wherein the input and/or output terminal is an output terminal that comprises:
a pad configured to be connected to the exterior of the circuit; and
a voltage adaptor circuit having an output coupled to the pad, and an input coupled to the circuit core, the adaptor circuit configured to be powered, by the terminal supply voltage and by the power supply voltage in order to transform an output signal received in a voltage range between zero volts and the power supply voltage into a signal in the range between zero volts and the power supply voltage.

5. The integrated circuit according to claim 4 wherein the output terminal is a logic output terminal that comprises a signal conditioning logic circuit coupling the output of the adaptor circuit to the pad, the signal conditioning logic circuit configured to be supplied with the terminal supply voltage.

6. The integrated circuit according to claim 4 wherein the output terminal comprises an output validation circuit coupling the output of the adaptor circuit to the pad, the validation circuit allowing the link between the adaptor circuit and the pad to be made, depending on a control signal.

7. The integrated circuit according to claim 1 wherein the input and/or output terminal is an input/output terminal that comprises:
a metal pad designed to be connected to the exterior of the integrated circuit;
a first voltage adaptor circuit having an input coupled to the pad, the first adaptor circuit configured to be powered by the terminal supply voltage and by the power supply voltage in order to transform an input signal received in a voltage range between zero volts and the terminal supply voltage into a signal in the range between zero volts and the power supply voltage;
a second voltage adaptor circuit having an output coupled to the pad, and an input coupled to the circuit core, the second adaptor circuit configured to be powered by the terminal supply voltage and by the power supply voltage in order to transform an output signal received in a voltage range between zero volts and the power supply voltage into a signal in the range between zero volts and the terminal supply voltage; and
an output validation circuit coupling the output of the second adaptor circuit to the pad, the validation circuit configured to allow the link between the second adaptor circuit and the pad to be made or not, depending on a control signal.

8. The integrated circuit according to claim 7 wherein the input/output terminal is a logic input/output terminal that comprises a first signal conditioning logic circuit having an input connected to an output of the first adaptor circuit and an output connected to the circuit core, the signal conditioning logic circuit configured to be supplied with the power supply voltage, and where the validation circuit is integrated into a second signal conditioning logic circuit.

9. The integrated circuit according to claim 1 wherein the circuit core is configured to be powered by a first power supply voltage delivered by the first power supply terminal, and by a second power supply voltage delivered by a third power supply terminal, and wherein the power supply voltage used by the input/output terminal is one of the first or second power supply voltages.

10. The integrated circuit according to claim 9 wherein at least one of the input and output terminal comprises protection means configured to limit the voltage present on the pad to the voltage level that is the higher of the first and second power supply voltages.

11. The integrated circuit according to claim 9 wherein the terminal supply voltage is in the range between the highest and the lowest power supply voltages.

12. The integrated circuit according to claim 1 wherein the second power supply terminal is coupled to at least one of the input/output terminals.

13. An integrated circuit comprising:
a first power supply terminal configured to receive a power supply voltage within a first range;
a circuit core coupled to the first power supply terminal;
an input/output terminal coupled to the circuit core;
a second power supply terminal configured to receive a terminal supply voltage within a second range; and
an adaptor circuit configured to be powered, by the terminal supply voltage, and by the power supply voltage, the adaptor circuit performing a transposition, of a signal flowing through the input/output terminal, from the first range to the second range.

14. The integrated circuit of claim 13 wherein the input/output terminal is a logic input terminal that comprises a logic signal conditioning circuit having an input connected to an output of the adaptor circuit, and an output connected to the circuit core, the logic signal conditioning circuit being configured to be supplied with the power supply voltage.

15. The integrated circuit of claim 13 wherein the input/output terminal is a logic output terminal that comprises a signal conditioning logic circuit coupling the output of the adaptor circuit to the pad, the signal conditioning logic circuit being configured to be supplied with the terminal supply voltage.

16. The integrated circuit of claim 13 wherein the input/output terminal comprises a pad configured to be connected to the exterior of the circuit, the integrated circuit further comprising an output validation circuit coupling an output of the adaptor circuit to the pad, the validation circuit allowing a link between the adaptor circuit and the pad to be made, depending on a control signal.

17. The integrated circuit of claim 13 wherein the input/output terminal comprises a metal pad designed to be connected to an exterior of the integrated circuit, and the adaptor circuit includes:
a first voltage adaptor circuit having an input coupled to the pad, the first adaptor circuit configured to be powered by the terminal supply voltage and by the power supply voltage in order to transform an input signal received in a voltage range between zero volts and the terminal supply voltage into a signal in the range between zero volts and the power supply voltage;
a second voltage adaptor circuit having an output coupled to the pad, and an input coupled to the circuit core, the second adaptor circuit configured to be powered by the terminal supply voltage and by the power supply voltage in order to transform an output signal received in a voltage range between zero volts and the power supply voltage into a signal in the range between zero volts and the terminal supply voltage; and
an output validation circuit coupling the output of the second adaptor circuit to the pad, the validation circuit configured to allow the link between the second adaptor circuit and the pad to be made or not, depending on a control signal.

18. The integrated circuit of claim 17 wherein the input/output terminal is a logic input/output terminal that comprises a first signal conditioning logic circuit having an input connected to an output of the first adaptor circuit and an output connected to the circuit core, the signal conditioning logic circuit being configured to be supplied with the power supply voltage, and where the validation circuit is integrated into a second signal conditioning logic circuit.

19. The integrated circuit of claim 13 wherein the circuit core is configured to be powered by a first power supply voltage delivered by the first power supply terminal, and by a second power supply voltage delivered by a third power supply terminal, and wherein the power supply voltage used by the input/output terminal is one of the first or second power supply voltages.

20. The integrated circuit of claim 19 wherein the input/output terminal comprises protection means configured to limit the voltage present on the pad to the voltage level that is the higher of the first and second power supply voltages.

21. An integrated circuit comprising:
a first power supply terminal configured to receive a power supply voltage within a first range;
an input/output terminal;
a second power supply terminal configured to receive a terminal supply voltage within a second range; and
an adaptor circuit coupled to the input/output terminal and the first and second power supply terminals and configured to transpose a signal flowing through the input/output terminal from the first range to the second range.

22. The integrated circuit of claim 21 wherein the input/output terminal is a logic input terminal that comprises a logic signal conditioning circuit having an input connected to an output of the adaptor circuit, and an output for connection to a circuit core, the logic signal conditioning circuit being configured to be supplied with the power supply voltage.

23. The integrated circuit of claim 21 wherein the input/output terminal is a logic output terminal that comprises a signal conditioning logic circuit coupling the output of the adaptor circuit to the pad, the signal conditioning logic circuit being configured to be supplied with the terminal supply voltage.

24. The integrated circuit of claim 21 wherein the input/output terminal comprises a conductive pad designed to be connected to an exterior of the integrated circuit, and the adaptor circuit includes:
a first voltage adaptor circuit having an input coupled to the pad, the first adaptor circuit configured to be powered by the terminal supply voltage and by the power supply voltage in order to transform an input signal received in a voltage range between zero volts and the terminal supply voltage into a signal in the range between zero volts and the power supply voltage; and
a second voltage adaptor circuit having an output coupled to the pad, and an input coupled to the circuit core, the second adaptor circuit configured to be powered by the terminal supply voltage and by the power supply voltage in order to transform an output signal received in a voltage range between zero volts and the power supply voltage into a signal in the range between zero volts and the terminal supply voltage.

25. The integrated circuit of claim 21, further comprising:
a first circuit core configured to be powered by a first power supply voltage;
a second circuit core configured to be powered by a second power supply voltage delivered by a third power supply terminal, and wherein the power supply voltage used by the input/output terminal is one of the first or second power supply voltages.

26. The integrated circuit of claim 25 wherein the input/output terminal comprises protection means configured to limit the voltage present on the pad to the voltage level that is the higher of the first and second power supply voltages.
